(19) United States
(12) Patent Application Publication
(10) Pub. No.: US 2026/0349356 A1
(43) Pub. Date: Nov. 5, 2026

(54) REDUCED VOLUME DEMULTIPLEXER SYSTEMS AND METHODS

(71) Applicant: ASML NETHERLANDS B.V., Veldhoven (NL)

(72) Inventors: Scott Douglas COSTON, New Milford, CT (US); Anirban MITRA, Wilton, CT (US); Yuxiang LIN, Wilton, CT (US); An MAO, Stamford, CT (US); Sergey MALYK, Bethel, CT (US); David TAUB, Stamford, CT (US)

(73) Assignee: ASML NETHERLANDS B.V., Veldhoven (NL)

(21) Appl. No.: 19/486,884

(22) PCT Filed: Apr. 25, 2024
(86) PCT No.: PCT/EP2024/061488

§ 371 Date: Nov. 21, 2025

Related U.S. Application Data
(60) Provisional application No. 63/468,506, filed on May 23, 2023.

(51) Int. Cl. G03F 7/00; G03F 9/00

(52) U.S. Cl. CPC G03F 7/706851; G03F 7/70266; G03F 7/70633; G03F 7/706849; G03F 9/7088

(57) ABSTRACT

A metrology system is described. Metasurfaces are used to replace (or to augment) an existing demultiplexer to reduce the volume of the demultiplexer in the metrology system. A metasurface is configured to receive a diffracted radiation beam from a radiation source, and separate the beam into a narrower band sub-beam of radiation having a modified wavelength range, amplitude, pulse frequency, pulse time, polarization state or states, angular content, and/or spatial content in comparison to an incident wavelength range, amplitude, pulse frequency, pulse time, polarization state or states, angular content, and/or spatial content.

### CROSS REFERENCE TO RELATED APPLICATION

This application claims priority to U.S. Application No. 63/468,506, filed May 23, 2023, and which is incorporated herein in its entirety by reference.

### TECHNICAL FIELD

This description relates to a reduced volume demultiplexer.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, deposition, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, deposition, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-ki lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but are not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

A metrology system is described. Metasurfaces are used to replace (or to augment) an existing demultiplexer to reduce the volume of the demultiplexer in the metrology system and/or for other purposes. A metasurface is configured to receive a diffracted radiation beam from a radiation source (e.g., a radiation beam that is generated by the source and then diffracted by a metrology mark and/or other target on a wafer and/or other substrate), and separate the beam into a narrower band sub-beam of radiation having a modified wavelength range, amplitude, pulse frequency, pulse time, polarization state or states, angular content, and/or spatial content in comparison to an incident wavelength range, amplitude, pulse frequency, pulse time, polarization state or states, angular content, and/or spatial content.

According to an embodiment, a metrology system is provided. The metrology system comprises a radiation source configured to form multiple diffracted radiation beams. Each of the diffracted radiation beams has an incident wavelength range, amplitude, pulse frequency, pulse time, polarization state or states, angular content, spatial content, and/or other characteristics. The metrology system comprises a radiation beam demultiplexer. The radiation beam demultiplexer comprises different sub-portions. Each of the different sub-portions is configured to separate an associated one of the diffracted radiation beams into a narrower band sub-beam of radiation having a modified wavelength range, amplitude, pulse frequency, pulse time, polarization state or states, angular content, and/or spatial content in comparison to the incident wavelength range, amplitude, pulse frequency, pulse time, polarization state or states, angular content, and/or spatial content. The metrology system comprises a detector configured to receive narrower band sub-beams of radiation and generate a detection signal.

In some embodiments, the metrology system forms a portion of an alignment sensor, an overlay sensor, and/or other sensors. The alignment and/or overlay sensor may be configured for a substrate comprising a semiconductor wafer. The alignment and/or overlay sensor may be configured to be used in a semiconductor manufacturing process. In some embodiments, the metrology system is configured for measuring alignment and/or overlay for one layer of the wafer relative to another.

In some embodiments, the different sub-portions comprise one or more metasurfaces. The one or more metasurfaces are configured to be usable with one or more lenses, optical fibers, detectors, mirrors, and/or integrated optics. In some embodiments, the one or more metasurfaces comprise nano-antennas, meta-atoms, scatterers, and/or nano-particles.

In some embodiments, the different sub-portions are geometrically configured for different non-overlapping wavelength ranges, amplitudes, pulse frequencies, pulse times, polarization states, angular content, and/or spatial content.

In some embodiments, each different sub-portion is associated with a different color wavelength range.

In some embodiments, the different sub-portions comprise adjacent local areas of a single unitary metasurface formed with nano-antennas, meta-atoms, or nano-particles configured for specific non-overlapping radiation wavelength ranges, amplitudes, pulse frequencies, pulse times, polarization states, angular content, and/or spatial content. In some embodiments, the different sub-portions comprise separate metasurfaces formed with nano-antennas, meta-atoms, or nano-particles configured for specific non-overlapping radiation wavelength ranges, amplitudes, pulse frequencies, pulse times, polarization states, angular content, and/or spatial content. In some embodiments, the nano-antennas, meta-atoms, scatterers, and/or nano-particles comprise blocks of material having heights, widths, lengths, and/or angles of rotation configured for a specific non-overlapping wavelength range, amplitude, pulse frequency, pulse time, polarization state, angular content, and/or spatial content. In some embodiments, the nano-antennas, meta-atoms, scatterers, and/or nano-particles comprise free form shapes configured for a specific wavelength range, amplitude, pulse frequency, pulse time, polarization state, angular content, and/or spatial content.

In some embodiments, the different sub-portions are configured to focus radiation of a specific wavelength range, amplitude, pulse frequency, pulse time, polarization state or states, angular content, and/or spatial content. In some embodiments, the different sub-portions are configured to collimate radiation of a specific wavelength range, amplitude, pulse frequency, pulse time, polarization state or states, angular content, and/or spatial content.

In some embodiments, first sub-portions are configured to disperse narrower band sub-beams of radiation, and second sub-portions are configured to collect and direct the narrower band sub-beams of radiation toward the detector. In some embodiments, the first and second sub-portions each comprise a two dimensional (2D) array of adjacent sub-portions. In some embodiments, the first and second sub-portions comprise a first metasurface, and a second metasurface spaced from the first metasurface, along an optical path. In some embodiments, the first metasurface is configured to receive the diffracted radiation beams from a target on a substrate, and filter the diffracted radiation for a specific wavelength range, amplitude, pulse frequency, pulse time, polarization state or states, angular content, and/or spatial content. The second metasurface is configured to separate the diffracted radiation beams into the narrower band sub-beams of radiation having the modified wavelength range, amplitude, pulse frequency, pulse time, polarization state or states, angular content, and/or spatial content; and direct the narrower band sub-beams of radiation toward the detector.

In some embodiments, the different sub-portions are configured to divide and disperse a diffracted radiation beam into a series of non-overlapping wavelength, amplitude, pulse frequency, pulse time, polarization state or states, angular content, and/or spatial content bands, collimate the wavelength, amplitude, pulse frequency, pulse time, polarization state or states, angular content, and/or spatial content bands, and/or focus each of the wavelength, amplitude, pulse frequency, pulse time, polarization state or states, angular content, and/or spatial content bands at a different spot on the detector.

In some embodiments, the metrology system comprises a grating configured to receive a diffracted radiation beam from a target on a substrate, and direct different wavelength, amplitude, pulse frequency, pulse time, polarization state or states, angular content, and/or spatial content ranges of the diffracted radiation beam toward different corresponding sub-portions associated with a given wavelength, amplitude, pulse frequency, pulse time, polarization state or states, angular content, and/or spatial content range.

In some embodiments, the metrology system comprises a liquid crystal polarizing grating and/or a prism configured to receive a diffracted radiation beam from a target on a substrate, and direct different wavelength, amplitude, pulse frequency, pulse time, polarization state or states, angular content, and/or spatial content ranges of the diffracted radiation beam toward different corresponding sub-portions associated with a given wavelength, amplitude, pulse frequency, pulse time, polarization state or states, angular content, and/or spatial content range.

In some embodiments, the different sub-portions comprise a series of metasurfaces spaced from each other along an optical path. Each metasurface in the series of metasurfaces is configured to reflect a narrower band sub-beam of radiation having the modified wavelength, amplitude, pulse frequency, pulse time, polarization state or states, angular content, and/or spatial content range toward the detector, while collimating and allowing a remaining portion of a diffracted radiation beam to pass through along the optical path.

In some embodiments, the detector comprises multiple separate detectors, or multiple sub-portions of a single detector.

In some embodiments, the different sub-portions are arranged to form a waveguide. The waveguide is configured to receive a diffracted radiation beam, separate the diffracted radiation beam into narrower band sub-beams of radiation having the modified wavelength, amplitude, pulse frequency, pulse time, polarization state or states, angular content, and/or spatial content range; and direct the narrower band sub-beams of radiation through the waveguide toward the detector.

In some embodiments, the radiation source is configured to generate the multiple diffracted radiation beams by directing a first incident radiation beam toward a target on a substrate such that the target diffracts the first incident radiation beam.

According to another embodiment, a metrology method is provided. The method comprises one or more of the operations described above performed by the metrology system.

### BRIEF DESCRIPTION OF THE DRAWINGS

The above aspects and other aspects and features will become apparent to those ordinarily skilled in the art upon review of the following description of specific embodiments in conjunction with the accompanying figures.

FIG. 1 schematically depicts a lithography apparatus, according to an embodiment.

FIG. 2 schematically depicts an embodiment of a lithographic cell or cluster, according to an embodiment.

FIG. 3 schematically depicts an example metrology system, according to an embodiment.

FIG. 4 schematically depicts an example metrology technique, according to an embodiment.

FIG. 5 illustrates the relationship between a radiation illumination spot of an inspection system and a metrology target, according to an embodiment.

FIG. 6 illustrates a reduced volume demultiplexer, according to an embodiment.

FIG. 7 illustrates a side view of one or more sub-portions of the reduced volume demultiplexer shown in FIG. 6, according to an embodiment.

FIG. 8 illustrates first and second sub-portions of a demultiplexer, which each comprise a two dimensional (2D) array of adjacent sub-portions, according to an embodiment.

FIG. 9 illustrates a grating configured to receive a diffracted radiation beam from a target on a substrate, and direct different wavelength ranges (in this example) of diffracted radiation toward different corresponding demultiplexer sub-portions associated with a given wavelength range, according to an embodiment.

FIG. 10 illustrates a liquid crystal polarizing grating and a prism configured to receive a polarized incident radiation beam from a target on a substrate, and direct different wavelength ranges (in this example) of the radiation toward different corresponding demultiplexer sub-portions associated with a given wavelength range, according to an embodiment.

FIG. 11 illustrates a practical example of how using demultiplexer sub-portions comprising metasurfaces reduces the volume of a demultiplexer, according to an embodiment.

FIG. 12 illustrates different sub-portions of a demultiplexer comprising a series of metasurfaces spaced from each other along an optical path, with each metasurface in the series of metasurfaces configured to reflect a narrower band sub-beam of radiation having a modified wavelength range (in this example) toward the detector, while collimating and allowing a remaining portion of a diffracted radiation beam to pass through along the optical path, according to an embodiment.

FIG. 13 illustrates different sub-portions of a demultiplexer arranged to form one or more waveguides, according to an embodiment.

FIG. 14 illustrates a metrology method, according to an embodiment.

FIG. 15 is a block diagram of an example computer system, according to an embodiment.

### DETAILED DESCRIPTION

In semiconductor device manufacturing, metrology operations typically include determining the position of a metrology target (or marks) and/or other target in a layer of a semiconductor device structure. This position is typically determined by irradiating a metrology target with radiation, and comparing characteristics of different diffraction orders of radiation diffracted from the metrology target. Such techniques are used to measure alignment, overlay, and/or other parameters. Prior metrology systems use a bulky, multi-element demultiplexer to transmit sub-portions of diffracted radiation from a target such as a metrology mark to a detector. These demultiplexers increase the costs and size of a typical metrology system, among other disadvantages.

For example, a demultiplexer is often used with an alignment sensor to separate multiple individual color bands from a single input into multiple outputs (channels). Prior alignment metrology system demultiplexers may use filters to separate colors, along with refractive and/or reflective optics to transmit light from input to output. Each alignment sensor needs one demultiplexer, and potentially additional filters, refractive and/or reflective optics, and/or other components for each output channel.

The optics used to transmit light from the input to the output comprise bulky lenses and/or other surfaces configured for bending light. These lenses and/or other surfaces can have substantial depth, taking up volume. In addition, as the number of colors (which correspond to output channels) used by an alignment sensor has grown, the size and quantity of required demultiplexers has also grown. If industry trends continue as expected, future metrology systems may require 20-30× more demultiplexers compared to today's systems. It is also likely that future systems will use multiple quantities of alignment sensors (10× for instance), which each require one or more additional demultiplexers. Finding the physical space necessary for these components may be impossible.

By considering known characteristics about a radiation beam, and by considering aspects of metasurface design, different sub-portions (e.g., metasurfaces) of a new demultiplexer described below are configured to function for an entire operating range of a typical diffracted radiation beam, and be adjustable for selecting, collimating, focusing, etc., a diffracted radiation beam from a target. The sub-portions described below may be broadband metasurfaces (e.g., as a whole, configured for radiation having a range of characteristics) which are locally narrowband (e.g., having different sub-portions configured to separate narrower band sub-beams of radiation). For example, a metasurface may be configured to receive a diffracted radiation beam from a radiation source, and separate the beam into a narrower band sub-beam (or beams) of radiation having a modified wavelength range, amplitude, pulse frequency, pulse time, polarization state or states, angular content, and/or spatial content in comparison to an incident wavelength range, amplitude, pulse frequency, pulse time, polarization state or states, angular content, and/or spatial content. Metasurfaces are much thinner (e.g., 100× or more thinner) than typical lenses and/or other components associated with a demultiplexer, which significantly reduces the volume of a demultiplexer, and/or has other advantages.

By way of a brief introduction, the description below relates to semiconductor device manufacturing and patterning processes. The following paragraphs also describe several components of systems and/or methods for semiconductor device metrology. These systems and methods may be used for measuring alignment, overlay, etc., in a semiconductor device manufacturing process, for example, or for other operations.

Although specific reference may be made in this text to the measurement of alignment, overlay, or other parameters, and the manufacture of integrated circuits (ICs) for semiconductor devices, it should be understood that the description herein has many other applications. For example, it may be employed in the manufacture of integrated optical systems, guidance and detection patterns for magnetic domain memories, display panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate” and “target portion,” respectively.

The term “projection optics” should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in a lithographic and/or metrology projection apparatus, no matter where the optical component is located on an optical path. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

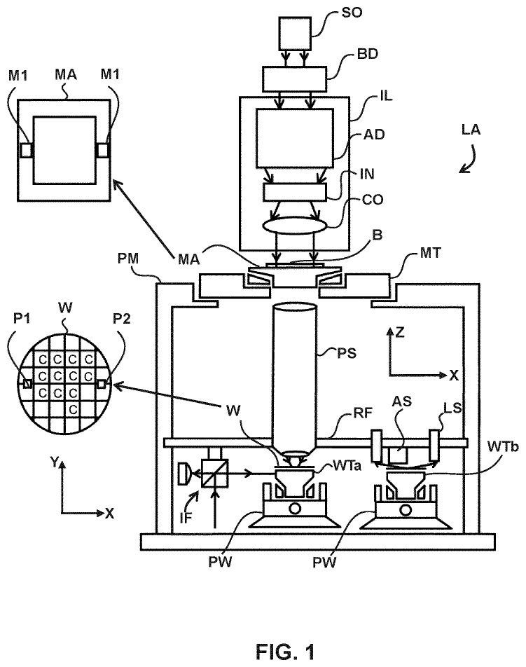

FIG. 1 schematically depicts an embodiment of a lithographic apparatus LA. The apparatus comprises an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, diffractive, electrostatic, or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” should be broadly interpreted as encompassing any type of projection system, including refractive, reflective, catadioptric, magnetic, electromagnetic, and electrostatic optical systems, or any combination thereof, as appropriate for the exposure radiation being used, or for other factors such as the use of an immersion liquid or the use of a vacuum. Any use of the term “projection lens” may be considered as synonymous with the more general term “projection system.”

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more supports or tables (e.g., two or more wafer tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be conducted on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above. Combinations and/or variations on the above-described modes of use or entirely different modes of use may also be employed.

The substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein with respect to lithography encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

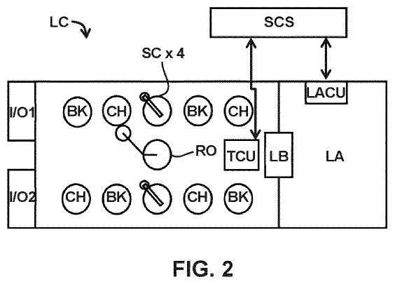

As shown in FIG. 2, the lithographic apparatus LA may form part of a lithographic cell LC, also sometimes referred to a lithocell or cluster, which also includes apparatuses to perform pre-and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on one or more dedicated metrology targets provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. A fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. Traditionally, this may be termed diffraction-based metrology. Applications of this diffraction-based metrology include the measurement of overlay, alignment, etc. For example, overlay and/or alignment can be measured by comparing parts of the diffraction spectrum (for example, comparing different diffraction orders in the diffraction spectrum of a periodic grating).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus LA or the lithocell LC, or may be a stand-alone device.

To enable the metrology, often one or more targets are specifically provided on the substrate. Typically, the target is specially designed and may comprise a periodic structure. For example, the target on a substrate may comprise one or more 1-D periodic structures (e.g., geometric features such as gratings), which are printed such that after development, the periodic structural features are formed of solid resist lines. As another example, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

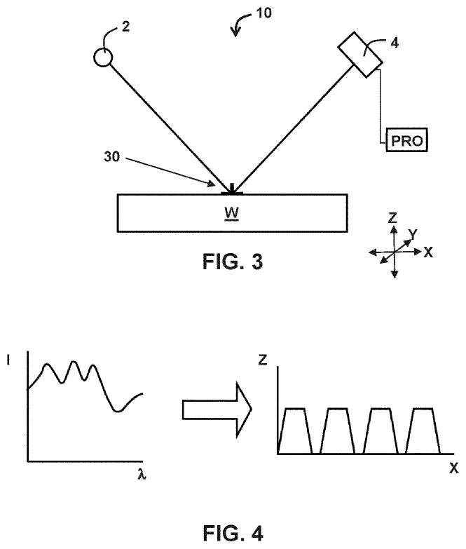

FIG. 3 depicts an example metrology (inspection) system 10 that may be used to detect alignment, overlay, and/or perform other metrology operations. It comprises a radiation or illumination source 2 which projects or otherwise irradiates radiation onto a substrate W (e.g., which may typically include a metrology mark). The redirected radiation is passed to a sensor such as a spectrometer detector 4 and/or other sensors, which measures a spectrum (intensity as a function of wavelength) of the specular reflected and/or diffracted radiation, as shown, e.g., in the graph on the left of FIG. 4. The sensor may generate a metrology signal conveying metrology data indicative of properties of the reflected and/or diffracted radiation. From this data, the structure or profile giving rise to the detected spectrum may be reconstructed by one or more processors PRO, or by other operations.

As in the lithographic apparatus LA in FIG. 1, one or more substrate tables may be provided to hold the substrate W during measurement operations. The one or more substrate tables may be similar or identical in form to the substrate table WT (WTa or WTb or both) of FIG. 1. In an example where system 10 is integrated with the lithographic apparatus, they may even be the same substrate table. Coarse and fine positioners may be provided and configured to accurately position the substrate in relation to a measurement optical system. Various sensors and actuators are provided, for example, to acquire the position of a target portion of interest of a structure (e.g., a metrology mark), and to bring it into position under an objective lens. Typically, many measurements will be made on target portions of a structure at different locations across the substrate W. The substrate support can be moved in X and Y directions to acquire different targets, and in the Z direction to obtain a desired location of the target portion relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and the substrate moves. Provided the relative position of the substrate and the optical system is correct, it does not matter in principle which one of those is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

For typical metrology measurements, a target 30 on substrate W may be a 1-D grating, which is printed such that after development, the bars are formed of solid resist lines (e.g., which may be covered by a deposition layer), and/or other materials. Or the target 30 may be a 2-D grating, which is printed such that after development, the grating is formed of solid resist pillars, and/or other features in the resist.

The bars, pillars, vias, and/or other features may be etched into or on the substrate (e.g., into one or more layers on the substrate), deposited on a substrate, covered by a deposition layer, and/or have other properties. Target 30 (e.g., of bars, pillars, vias, etc.) is sensitive to changes in processing in the patterning process (e.g., optical aberration in the lithographic projection apparatus such as in the projection system, focus change, dose change, etc.) such that process variation manifests in variation in target 30. Accordingly, the measured data from target 30 may be used to determine an adjustment for one or more of the manufacturing processes, and/or used as a basis for making the actual adjustment.

For example, the measured data from target 30 may indicate alignment and/or overlay for a layer of a semiconductor device. The measured data from target 30 may be used (e.g., by the one or more processors PRO and/or other processors) for determining one or more semiconductor device manufacturing process parameters based the alignment and/or overlay, and determining an adjustment for a semiconductor device manufacturing apparatus based on the one or more determined semiconductor device manufacturing process parameters. In some embodiments, this may comprise a stage position adjustment, for example, or this may include determining an adjustment for a mask design, a metrology target design, a semiconductor device design, an intensity of the radiation, an incident angle of the radiation, a wavelength of the radiation, a pupil size and/or shape, a resist material, and/or other process parameters.

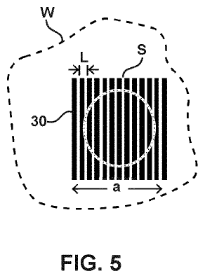

FIG. 5 illustrates a plan view of a typical target 30, and the extent of a typical radiation illumination spot. Typically, to obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target, in other words, is ‘underfilled’ by the illumination, and the diffraction signal is essentially free from any signals from product features and the like outside the target itself. The illumination arrangement may be configured to provide illumination of a uniform intensity across a back focal plane of an objective, for example. Alternatively, by, for example, including an aperture in the illumination path, illumination may be restricted to on axis or off axis directions.

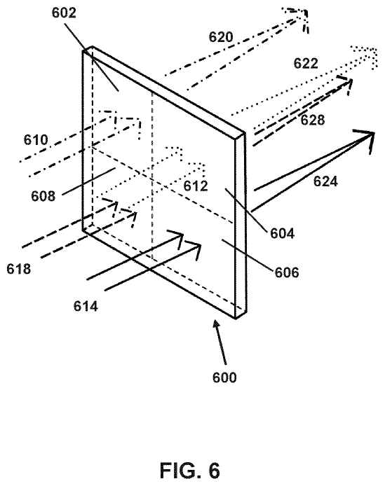

FIG. 6 illustrates a radiation beam demultiplexer 600 that may be included in a metrology system such as metrology system 10 shown in FIG. 3, for example. The radiation beam demultiplexer 600 comprises different sub-portions 602, 604, 606, and 608. Each of the different sub-portions 602-608 is configured to separate an associated diffracted radiation beam 610, 612, 614, and 618 into a narrower band sub-beam 620, 622, 624, and 626 of radiation having a modified wavelength range, amplitude, pulse frequency, pulse time, polarization state or states, angular content, spatial content and/or other characteristics in comparison to an incident wavelength range, amplitude, pulse frequency, pulse time, polarization state or states, angular content, spatial content, and/or other characteristics. In the case of a beam with spatial content, the constituents are separate by a spatial dimension (X, Y). In the case of a beam with angular content, the constituents have different propagation directions. A lens can be used to convert spatial content into angular content or vice-a-versa. Radiation having a modified wavelength range, amplitude, pulse frequency, pulse time, polarization state or states, angular content, spatial content and/or other characteristics in comparison to an incident wavelength range, amplitude, pulse frequency, pulse time, polarization state or states, angular content, spatial content, and/or other characteristics may comprise narrowed and/or constituent radiation. For example, modified sub-beam radiation may comprise radiation having a certain wavelength range within a broader wavelength range of the incident radiation.

Note that FIG. 6 presents a simplified view of an example demultiplexer 600, with representative sub-portions and arrows for the different radiation beams meant to be examples only. In this example, demultiplexer 600 is a broadband metasurface (e.g., as a whole, configured for multicolored light) which is locally narrowband (e.g., having different sub-portions 602-608 configured to transmit the separate narrower band—single color or shade of gray in this example—sub-beams 620-626 of radiation), for example. In this particular illustration, sub-portions 602-608 are also configured to focus the various sub-beams 620-626 at different locations. Additional details related to all of these features are described below.

Demultiplexer 600 may be used in a metrology system such as system 10 shown in FIG. 3 to replace or augment a demultiplexer configured for directing radiation from one or more metrology targets 30 (FIG. 3), such as one or more diffraction grating targets. The radiation may be used to obtain images of the metrology targets, and/or for other uses. The radiation may comprise illumination such as light and/or other radiation. A target 30 may comprise one or more metrology marks, such as diffraction grating targets, formed in a substrate such as a semiconductor wafer, for example. Demultiplexer 600 may form a portion of an alignment sensor and/or an overlay detection sensor represented by system 10 (FIG. 3), as described herein. The alignment sensor and/or the overlay detection sensor may be configured for a semiconductor wafer, for example, and may be used in a semiconductor manufacturing process. In some embodiments, the metrology system is configured for measuring alignment and/or overlay for one layer of the wafer relative to another. In some embodiments, the metrology system might have multiple parallel alignment sensors so that alignment of a wafer and/or other substrate may be performed more quickly.

As described above, the metrology system (e.g., system 10 shown in FIG. 3) comprises a radiation source (e.g., source 2) configured to form multiple diffracted radiation beams. Each of the diffracted radiation beams has an incident wavelength range, amplitude, pulse frequency, pulse time, polarization state or states, angular content, spatial content, and/or other characteristics. The metrology system also comprises a detector (e.g., detector 4, processor PRO, and/or other components) configured to receive narrower band sub-beams of radiation 620-626 and generate a detection signal. In some embodiments, the radiation source is configured to generate the multiple diffracted radiation beams 610-618 by directing a first incident radiation beam toward a target (e.g., target 30 shown in FIG. 3) on a substrate (e.g., substrate W shown in FIG. 3) such that the target diffracts the first incident radiation beam (e.g., see the beams drawn between source 2, target 30, and detector 4 shown in FIG. 3).

In some embodiments, the different sub-portions 602-608 are geometrically configured for different non-overlapping wavelength ranges, amplitudes, pulse frequencies, pulse times, polarization states, angular content, spatial content, and/or other characteristics of diffracted radiation beams 610, 612, 614, and 618. For example, the different sub-portions 602-608 may comprise one or more metasurfaces. Metasurfaces are generally flat optics that use small, sub-wavelength geometrical features to perform various functions (e.g., as described herein). In some embodiments, a metasurface can act as a powered surface. A powered surface is an optical surface that bends the incident light. A lens often has a front powered surface and a back powered surface, for example.

In some embodiments, the one or more metasurfaces comprise nano-antennas, meta-atoms, scatterers, and/or nano-particles. The nano-antennas, meta-atoms, scatterers, and/or nano-particles may comprise blocks of material having heights, widths, lengths, and/or angles of rotation configured for a specific non-overlapping wavelength range, amplitude, pulse frequency, pulse time, polarization state, angular content, spatial content, and/or other characteristics. In some embodiments, the nano-antennas, meta-atoms, scatterers, and/or nano-particles comprise free form shapes configured for a specific wavelength range, amplitude, pulse frequency, pulse time, polarization state, angular content, spatial content and/or other characteristics. In the example shown in FIG. 6, each different sub-portion 602-608 is associated with (e.g., the nano-antennas, meta-atoms, scatterers, and/or nano-particles are configured for) a different color wavelength range.

FIG. 6 illustrates demultiplexer 600 as a shared common optical component across multiple input channels (e.g., diffracted radiation beams 610, 612, 614, and 618). Compared to prior systems, demultiplexer 600 essentially combines what would have been multiple demultiplexers into a single demultiplexer. FIG. 6 shows how a single demultiplexer 600 can be used across four channels (in this example—10's, 100's, 1000's or more channels are possible using the principles described herein).

In some embodiments, the different sub-portions 602-608 comprise adjacent local areas of a single unitary metasurface (e.g., demultiplexer 600 in this example) formed with nano-antennas, meta-atoms, or nano-particles configured for specific non-overlapping radiation wavelength ranges, amplitudes, pulse frequencies, pulse times, polarization states, angular content, spatial content, and/or other characteristics of diffracted radiation beams 610, 612, 614, and 618. In some embodiments, the different sub-portions comprise separate metasurfaces (e.g., formed with nano-antennas, meta-atoms, or nano-particles configured for specific non-overlapping radiation wavelength ranges, amplitudes, pulse frequencies, pulse times, polarization states, angular content, spatial content, and/or other characteristics). Even though this separate metasurface example is not shown in FIG. 6, one can easily imagine space between each sub-portion 602-608 shown in FIG. 6. The one or more sub-portions 602-608 (e.g., metasurfaces), whether adjacent or separate, are configured to be usable by themselves and/or with one or more lenses, optical fibers, detectors, mirrors, and/or integrated optics of the metrology system.

In some embodiments, as shown in FIG. 6, the different sub-portions 602-608 are configured to focus radiation (e.g., sub-beams 620-626) of a specific wavelength range, amplitude, pulse frequency, pulse time, polarization state or states, angular content, spatial content, and/or other characteristics. In some embodiments, the different sub-portions are configured to collimate radiation of a specific wavelength range, amplitude, pulse frequency, pulse time, polarization state or states, angular content, spatial content, and/or other characteristics. In some embodiments, the different sub-portions 602-608 are configured to divide and disperse a diffracted radiation beam 610-618 (e.g., individually or collectively) into a series of non-overlapping wavelength, amplitude, pulse frequency, pulse time, polarization state or states, angular content, spatial content, and/or other characteristic bands, collimate this radiation, and/or focus this radiation at different spots on the detector.

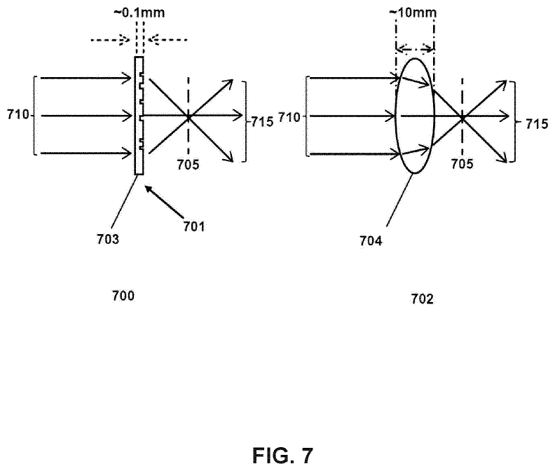

FIG. 7 illustrates a side view 700 of a demultiplexer 701 comprising a metasurface 703 (e.g., similar to and/or the same as one or more of sub-portion 602-608 of demultiplexer 600 shown in FIG. 6). Side view 700 of demultiplexer 701 is compared to side view 702 of a typical lens 704 included in a prior demultiplexer. As shown in FIG. 7, both demultiplexer 701 (metasurface 703) and lens 704 can be configured to focus 705 (in this example) and/or otherwise transmit 715 incident radiation 710. However, metasurface 703 is much thinner (e.g., 100× thinner or more) than typical lens 704 and/or other components associated with prior demultiplexers, which significantly reduces the volume of demultiplexer 701, provides for less complex mounts for demultiplexer 701, and less optical yielding compared to prior systems. In addition, since demultiplexer 701 comprises a single flat substrate, and is easier to mount in a metrology system (e.g., system 10 shown in FIG. 3) compared to conventional optics, it is thus more robust against environmental changes and possible cost reduction requirements for the metrology system. Demultiplexer 701 also facilitates cost reduction compared to prior systems because multiple channels are processed through a common optical component, reducing the number of individual elements to manufacture and mount compared to a typical metrology system. Costs may also be reduced because a quantity of high precession optical surfaces is less when demultiplexer 701 is used in a metrology system. Demultiplexer 701 also reduces the mass reduction of a typical demultiplexer because of the significantly reduced thickness. Similar principles may also be used to configure demultiplexer 701 as a combiner, rather than a separator. Other advantages are contemplated.

In some embodiments, first sub-portions of a demultiplexer such as demultiplexer 600 (FIG. 6) and/or demultiplexer 701 (FIG. 7) are configured to disperse narrower band sub-beams of radiation, and second sub-portions are configured to collect and direct the narrower band sub-beams of radiation toward the detector. For example, in some embodiments, the first and second sub-portions each comprise a two dimensional (2D) array of adjacent sub-portions (e.g., as shown in FIG. 6). In some embodiments, the first and second sub-portions comprise a first metasurface (e.g., a thin square or rectangularly shaped metasurface as shown in FIG. 6 or FIG. 7), and a second metasurface (e.g., a second rectangularly shaped metasurface) spaced from the first metasurface, along an optical path. In some embodiments, the first metasurface is configured to receive the diffracted radiation beams from a target on a substrate, and filter the diffracted radiation for a specific wavelength range, amplitude, pulse frequency, pulse time, polarization state or states, angular content, and/or spatial content. The second metasurface is configured to separate the diffracted radiation beams into the narrower band sub-beams of radiation having the modified wavelength range, amplitude, pulse frequency, pulse time, polarization state or states, angular content, and/or spatial content; and direct the narrower band sub-beams of radiation toward the detector.

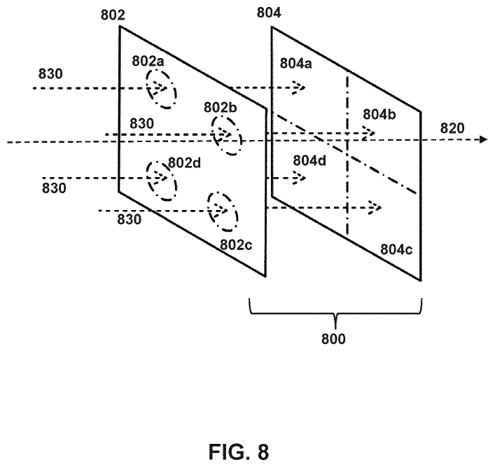

FIG. 8 illustrates an example of such an embodiment. FIG. 8 illustrates first and second sub-portions 802 and 804 of a demultiplexer 800, which each comprise a two dimensional (2D) array of adjacent sub-portions (e.g., 802a, 802b, 802c, and 802d; and 804a, 804b, 804c, and 804d). In this example, first and second sub-portions 802 and 804 comprise a first metasurface (e.g., a thin square or rectangularly shaped metasurface as shown in FIG. 6 or FIG. 7), and a second metasurface (e.g., a second rectangularly shaped metasurface) spaced from the first metasurface, along an optical path 820. In some embodiments, the first metasurface (sub-portion 802) is configured to receive the diffracted radiation beams 830 from a target on a substrate (e.g., see FIG. 3), and filter the diffracted radiation for a specific wavelength range, amplitude, pulse frequency, pulse time, polarization state or states, angular content, and/or spatial content. The second metasurface (sub-portion 804) is configured to separate the diffracted radiation beams into the narrower band sub-beams of radiation having the modified wavelength range, amplitude, pulse frequency, pulse time, polarization state or states, angular content, and/or spatial content; and direct the narrower band sub-beams of radiation toward the detector (see FIG. 3, FIG. 6, FIG. 7, and the corresponding discussion above). As shown in FIG. 8, when combining multiple channels, a typical optical filter, being another flat optical component, can be made large enough to allow multiple beams to share a single optical component. Likewise, a single substate (sub portion 802 in this example) can be configured to include multiple independent metasurfaces (e.g., 2D array of sub-portions 802a, 802b, 802c, and 802d), reducing the total volume as compared to using a typical lens and/or optical filter.

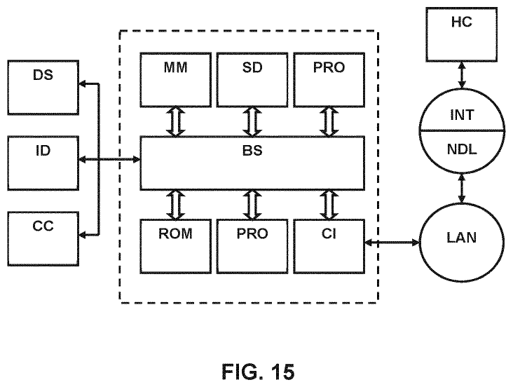

In some embodiments, a mechanical system (e.g., controlled by processor PRO shown in FIG. 3 and also in FIG. 15 discussed below) is configured to adjust the spacing between sub-portions 802 and 804, between a sub-portion and a detector, between a grating (and/or other diffractors) and a sub-portion (e.g., see figures and discussion below), and/or control other parameters. Processor PRO may be included in a computing system (e.g., CS in FIG. 15) and may operate based on computer or machine readable instructions MRI (e.g., as described below related to FIG. 15). Electronic communication may occur by transmitting electronic signals between separate components, transmitting data between separate components, transmitting values between separate components, and/or other communication. The components of a metrology system (e.g., system 10 shown in FIG. 3) may communicate via wires or wirelessly via a network, such as the Internet or the Internet in combination with various other networks, like local area networks, cellular networks, or personal area networks, internal organizational networks, and/or other networks.

In some embodiments, one or more actuators may be coupled to and configured to move one or more components described herein. The actuators may be coupled to one or more of these components by adhesive, clips, clamps, screws, a collar, and/or other mechanisms. The actuators may be configured to be controlled electronically. Individual actuators may be configured to convert an electrical signal into mechanical displacement. The mechanical displacement is configured to move a component, such as one or more metasurfaces. As an example, one or more of the actuators may be piezoelectric. One or more processors PRO may be configured to control the actuators. One or more processors PRO may be configured to individually control each of the one or more actuators.

In some embodiments, the metrology system (e.g., system 10 shown in FIG. 3) comprises a grating configured to receive a diffracted radiation beam from a target (e.g., target 30 shown in FIG. 3) on a substrate (e.g. substrate W shown in FIG. 3), and direct different wavelength, amplitude, pulse frequency, pulse time, polarization state or states, angular content, and/or spatial content ranges of the diffracted radiation beam toward different corresponding sub-portions (e.g., sub-portions 602-608 shown in FIG. 6, and/or corresponding sub-portions shown in FIG. 7 and/or FIG. 8) associated with a given wavelength, amplitude, pulse frequency, pulse time, polarization state or states, angular content, and/or spatial content range.

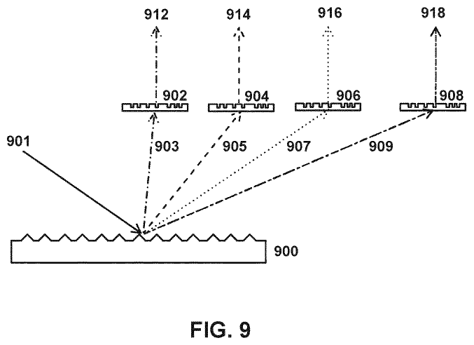

By way of a non-limiting example, FIG. 9 illustrates a grating 900 configured to receive a diffracted radiation beam 901 from a target on a substrate (not shown in FIG. 9), and direct different wavelength ranges (in this example—shown by differently shaded gray arrows 903, 905, 907, 909, but could be many other characteristics as described above) of diffracted radiation beam 901 toward different corresponding sub-portions 902, 904, 906, 908 (e.g., which may be similar to and/or the same as sub-portions 602-608 shown in FIG. 6, and/or corresponding sub-portions shown in FIG. 7 and/or FIG. 8). Each sub portion may be associated with a given wavelength range. In this example, sub-portions 902, 904, 906, 908 comprise separate individual metasurfaces. The separate individual metasurfaces are configured to collimate and/or otherwise transmit and direct (or re-direct) radiation 912, 914, 916, and 918 toward a detector (not shown in FIG. 9). Grating 900 may be configured to separate beam 901 into specific wavelength ranges and direct the specific wavelength ranges to different sub-portions 902-908 of a demultiplexer (e.g., demultiplexer 600 in FIG. 6, demultiplexer 701 in FIG. 7, etc.). In some embodiments, grating 900 may be configured for spatially separating incident radiation beam 901 by color into different wavelength groups and/or other diffracting. This may be used to replace reflective and refractive type optical elements in a prior optical system, for example.

The diffracted radiation beam 901 has a known wavelength range. This known wavelength range can be used to configure sub-portions 902-908. As shown in FIG. 9, in some embodiments, sub-portions 902-908 may be configured to collimate transmitted radiation 912-918. In some embodiments, sub-portions 902-908 may be configured to focus transmitted radiation toward a target. In some embodiments, sub-portions 902-908 may be configured to direct radiation 912-918 at different spots on a detector, and/or in other locations.

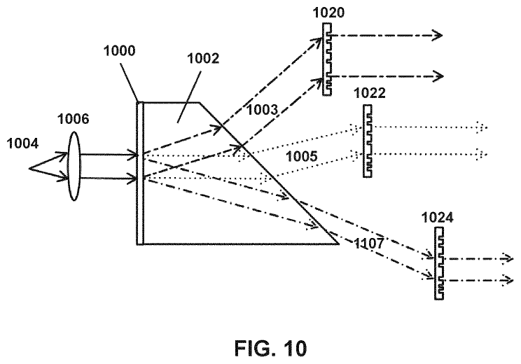

In some embodiments, the metrology system (e.g., system 10 shown in FIG. 3) comprises a liquid crystal polarizing grating and/or a prism configured to receive a polarized (diffracted) radiation beam from a target on a substrate, and direct different wavelength, amplitude, pulse frequency, pulse time, polarization state or states, angular content, and/or spatial content ranges of the diffracted radiation beam toward different corresponding sub-portions associated with a given wavelength, amplitude, pulse frequency, pulse time, polarization state or states, angular content, and/or spatial content range. FIG. 10 illustrates an example of such an embodiment. FIG. 10 illustrates a liquid crystal polarizing grating 1000 and a prism 1002 configured to receive a diffracted radiation beam 1004 (by way of a collimating lens 1006 in this example) from a target on a substrate (not shown in FIG. 10), and direct different wavelength ranges (in this example—shown by differently shaded gray arrows 1003, 1005, 1007, but could be many other characteristics as described above) of the diffracted radiation beam 1004 toward different corresponding sub-portions 1020, 1022, 1024 associated with a given wavelength range (e.g., which may similar to and/or the same as sub-portions 602-608 shown in FIG. 6, and/or corresponding sub-portions shown in FIG. 7, FIG. 8, and/or FIG. 9). In this example, sub-portions 1020-1024 comprise separate individual metasurfaces. The separate individual metasurfaces are configured to collimate and/or otherwise transmit and direct (or re-direct) radiation 1003-1007 toward a detector (not shown in FIG. 10). A liquid crystal polarization grating 1000 (LCPG) combined with a prism 1002 can be used as a Grating Prism (GRISM). As shown in FIG. 10, the GRISM separates the wavelengths by directing them into different propagation angles. LCPGs can be cascaded in the GRISM and/or other optical system to provide more angle separation between wavelength if needed.

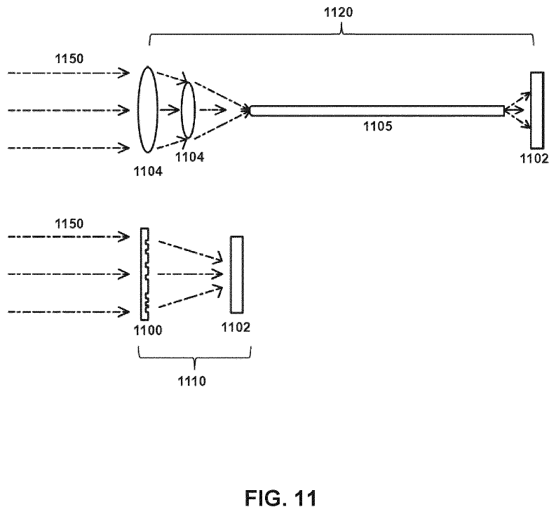

FIG. 11 illustrates a practical example of how using one or more sub-portions comprising metasurfaces (as described above) reduces the volume of a demultiplexer. FIG. 11 illustrates a demultiplexer 1100 (metasurface)/detector 1102 hybrid using metasurfaces instead of refractive optics 1104 and a fiber 1105 (fiber 1105 is required to relay the radiation beam to an area with more volume), thus shrinking the required volume 1110 compared to 1120. In this example, demultiplexer 1100 (metasurface) directs incident radiation 1150 directly to detector 1102, instead of into a fiber 1105. Using demultiplexer 1100 means that fiber 1105 is not required, allowing for detector 1102 to be place in close proximity to demultiplexer 1100. The use of a metasurface facilitates shrinking the volume of a typical demultiplexer arrangement (e.g., optics 1104 in combination with fiber 1105) such that demultiplexer 1100 can be combined with detector 1102, creating a demultiplexer/detector hybrid demultiplexer. Prior demultiplexers may have several output fibers 1105 (e.g., one per color and/or some other quantity) that run long distances between a demultiplexer module and a detection module. These modules are separated due to the limited volume available for both to be in the same location in a typical metrology system. Reducing the demultiplexer's size can open up the available volume to allow a combined demultiplexer/detection module, and/or have other advantageous effects.

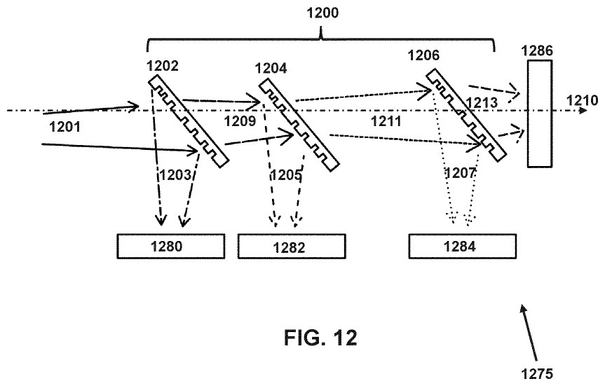

As shown in FIG. 12, in some embodiments, different sub-portions 1202, 1204, 1206 of a demultiplexer 1200 comprise a series of metasurfaces spaced from each other along an optical path 1210. Each metasurface in the series of metasurfaces is configured to (receive incident beam 1201 and) reflect a narrower band sub-beam of radiation 1203, 1205, 1207 having the modified wavelength, amplitude, pulse frequency, pulse time, polarization state or states, angular content, and/or spatial content range toward the detector, while collimating and allowing a remaining portion 1209, 1211, 1213 of a diffracted radiation beam to pass through along optical path 1210. In this example each metasurface in the series of metasurfaces is configured to reflect a narrower band sub-beam of radiation 1203, 1205, 1207 having a modified wavelength range-shown by differently shaded gray arrows, but could be many other characteristics as listed. In this example, the metasurfaces keep light collimated and/or semi-collimated in transmission, but focus a single color on reflection.

As described above, prior demultiplexers required a large volume. This large volume allowed for adequate lateral separation between colors of radiation (in this example) and couple each color into an output channel, while keeping the remaining colors from diverging as they propagated through the system. Metasurfaces can be used as shown in FIG. 12 and described above to select single colors and direct radiation of those colors to a detector, while keeping the other colors collimated (or semi-collimated) as they propagate through the metrology system (e.g., system 10 shown in FIG. 3), resulting in a reduced volume for the demultiplexing and/or detection. In some embodiments, as shown in FIG. 12, a detector 1275 e.g., similar to and/or the same as detector 4 shown in FIG. 3) may comprise multiple separate detectors 1280, 1282, 1284, 1286, multiple sub-portions of a single detector, and/or other arrangements.

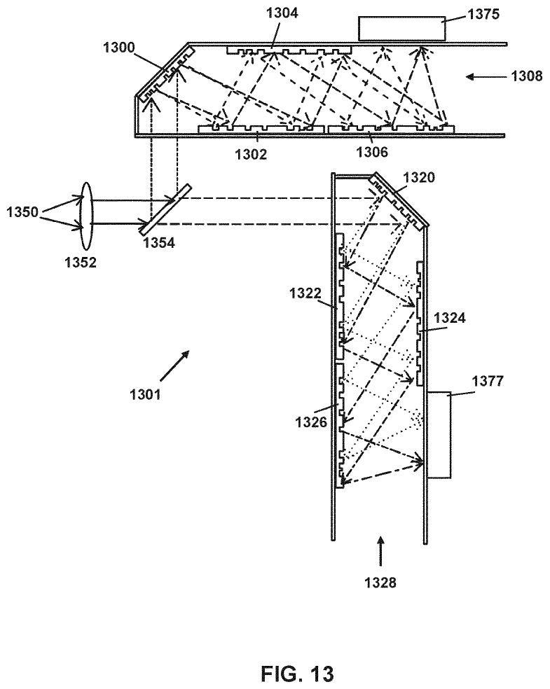

As shown in FIG. 13, in some embodiments, different sub-portions of a demultiplexer 1301 may be arranged to form one or more waveguides. FIG. 13 illustrates sub-portions 1300, 1302, 1304, and 1306 arranged to form a first waveguide 1308; and sub-portions 1320, 1322, 1324, and 1326 arranged to form a second waveguide 1328. Waveguides 1308 and 1328 are configured to receive a diffracted radiation beam 1350 (by way of a collimating lens 1352 and a bandpass filter 1354 in this example), separate the diffracted radiation beam into narrower band sub-beams (see the arrows of different shades of gray in FIG. 13) of radiation having a modified wavelength, amplitude, pulse frequency, pulse time, polarization state or states, angular content, and/or spatial content range (a modified and/or narrowed wavelength range is used in this example); and direct the narrower band sub-beams of radiation through the waveguides toward a detector (comprising detector sub-portions 1375 and 1377 in this example). In this embodiment, a metasurface acts as a grating, in conjunction with a waveguide, to fold the radiation, replacing refractive and reflective optics in typical demultiplexers, thus saving volume. Input radiation (beam 1350) can be split by a bandpass filter 1354 into several wavelength bands. Each band is coupled into a wedged waveguide (1308 or 1328) with metasurfaces (sub-portions 1300-1306 or sub-portions 1320-1326). The metasurfaces may function as a lens and/or grating to increase the dispersion of different wavelengths and focus them into different locations on the sides of the waveguide. The separated wavelengths can be collected by detector sub-portions 1375 and 1377. Note that FIG. 13 shows two waveguides as an example only. This structure is expandable to include several more waveguides.

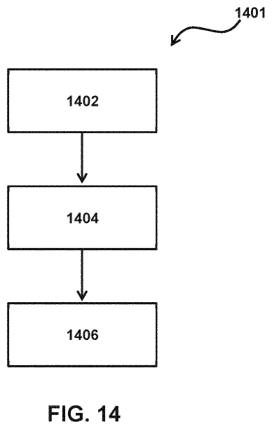

FIG. 14 illustrates a metrology method 1401. In some embodiments, method 1401 is performed as part of an alignment and/or overlay sensing operation in a semiconductor device manufacturing process, for example. In some embodiments, one or more operations of method 1401 may be implemented in or by a metrology system such as system 10 illustrated in FIG. 3, a metasurface such as those illustrated in FIG. 6-13, a computer system (e.g., as illustrated in FIG. 15 and described below), and/or in or by other systems, for example. In some embodiments, method 1401 comprises forming (operation 1402) multiple diffracted radiation beams, separating the multiple diffracted radiation beams into narrower band sub-beams (operation 1404), generating (operation 1406) a detection signal, and/or other operations.

The operations of method 1401 are intended to be illustrative. In some embodiments, method 1401 may be accomplished with one or more additional operations not described, and/or without one or more of the operations discussed. For example, in some embodiments, method 1401 may include an additional operation comprising determining overlay and/or alignment for a semiconductor wafer, and determining an adjustment for a semiconductor device manufacturing process. Additionally, the order in which the operations of method 1401 are illustrated in FIG. 14 and described herein is not intended to be limiting.

In some embodiments, one or more portions of method 1401 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1401 in response to instructions stored electronically on an electronic storage medium. The one or more processing devices may include one or more devices configured through hardware, firmware, and/or software to be specifically designed for execution of one or more of the operations of method 1401 (e.g., see discussion related to FIG. 15 below).

At operation 1402, multiple diffracted radiation beams are formed. The multiple diffracted radiation beams may be formed by a radiation source (see source 2 in FIG. 3), a target on a substrate such as a grating on a semiconductor wafer, and/or other components. Each of the diffracted radiation beams has an incident wavelength range, amplitude, pulse frequency, pulse time, polarization state or states, angular content, spatial content, and/or other characteristics. In some embodiments, the radiation source is configured to generate the multiple diffracted radiation beams by directing a first incident radiation beam toward a target on a substrate such that the target diffracts the first incident radiation beam.

At operation 1404, the multiple diffracted radiation beams are separated into narrower band sub-beams. A radiation beam demultiplexer (e.g., as shown and described above) is configured to perform the separating. The radiation beam demultiplexer comprises different sub-portions and/or other components. Each of the different sub-portions is configured to separate an associated one of the diffracted radiation beams into a narrower band sub-beam of radiation having a modified wavelength range, amplitude, pulse frequency, pulse time, polarization state or states, angular content, and/or spatial content in comparison to the incident wavelength range, amplitude, pulse frequency, pulse time, polarization state or states, angular content, and/or spatial content. The sub-beams may be transmitted toward the detector, for example.

As one example, the separate narrower band sub-beams of radiation may comprise locally bandwidth narrowed non-overlapping sub-beams of radiation having a modified amplitude, phase, and/or polarization. Each sub-portion may associated with a different color wavelength group and has a wavelength bandwidth for the associated color, for example.

In some embodiments, the different sub-portions (of the radiation beam demultiplexer) comprise one or more metasurfaces. The one or more metasurfaces may be useable by themselves, and/or the one or more metasurfaces may be configured to be usable with one or more lenses, optical fibers, detectors, mirrors, and/or integrated optics. In some embodiments, the one or more metasurfaces comprise nano-antennas, meta-atoms, scatterers, and/or nano-particles. In some embodiments, the different sub-portions are geometrically configured for different non-overlapping wavelength ranges, amplitudes, pulse frequencies, pulse times, polarization states, angular content, and/or spatial content.

In some embodiments, the different sub-portions comprise adjacent local areas of a single unitary metasurface formed with nano-antennas, meta-atoms, or nano-particles configured for specific non-overlapping radiation wavelength ranges, amplitudes, pulse frequencies, pulse times, polarization states, angular content, and/or spatial content. In some embodiments, the different sub-portions comprise separate metasurfaces formed with nano-antennas, meta-atoms, or nano-particles configured for specific non-overlapping radiation wavelength ranges, amplitudes, pulse frequencies, pulse times, polarization states, angular content, and/or spatial content. In some embodiments, the nano-antennas, meta-atoms, scatterers, and/or nano-particles comprise blocks of material having heights, widths, lengths, and/or angles of rotation configured for a specific non-overlapping wavelength range, amplitude, pulse frequency, pulse time, polarization state, angular content, and/or spatial content. In some embodiments, the nano-antennas, meta-atoms, scatterers, and/or nano-particles comprise free form shapes configured for a specific wavelength range, amplitude, pulse frequency, pulse time, polarization state, angular content, and/or spatial content.

In some embodiments, the different sub-portions are configured to focus radiation of a specific wavelength range, amplitude, pulse frequency, pulse time, polarization state or states, angular content, and/or spatial content. In some embodiments, the different sub-portions are configured to collimate radiation of a specific wavelength range, amplitude, pulse frequency, pulse time, polarization state or states, angular content, and/or spatial content.

In some embodiments, first sub-portions are configured to disperse narrower band sub-beams of radiation, and second sub-portions are configured to collect and transmit and/or otherwise direct the narrower band sub-beams of radiation toward the detector. In some embodiments, the first and second sub-portions each comprise a two dimensional (2D) array of adjacent sub-portions. In some embodiments, the first and second sub-portions comprise a first metasurface, and a second metasurface spaced from the first metasurface, along an optical path. In some embodiments, the first metasurface is configured to receive the diffracted radiation beams from a target on a substrate, and filter the diffracted radiation for a specific wavelength range, amplitude, pulse frequency, pulse time, polarization state or states, angular content, and/or spatial content. The second metasurface is configured to separate the diffracted radiation beams into the narrower band sub-beams of radiation having the modified wavelength range, amplitude, pulse frequency, pulse time, polarization state or states, angular content, and/or spatial content; and direct the narrower band sub-beams of radiation toward the detector.

In some embodiments, the different sub-portions are configured to divide and disperse a diffracted radiation beam into a series of non-overlapping wavelength, amplitude, pulse frequency, pulse time, polarization state or states, angular content, and/or spatial content bands, collimate the wavelength, amplitude, pulse frequency, pulse time, polarization state or states, angular content, and/or spatial content bands, and/or focus each of the wavelength, amplitude, pulse frequency, pulse time, polarization state or states, angular content, and/or spatial content bands at a different spot on the detector.

In some embodiments, the metrology system comprises a grating configured to receive a diffracted radiation beam from a target on a substrate, and direct different wavelength, amplitude, pulse frequency, pulse time, polarization state or states, angular content, and/or spatial content ranges of the diffracted radiation beam toward different corresponding sub-portions associated with a given wavelength, amplitude, pulse frequency, pulse time, polarization state or states, angular content, and/or spatial content range.

In some embodiments, the metrology system comprises a liquid crystal polarizing grating and/or a prism configured to receive a diffracted radiation beam from a target on a substrate, and direct different wavelength, amplitude, pulse frequency, pulse time, polarization state or states, angular content, and/or spatial content ranges of the diffracted radiation beam toward different corresponding sub-portions associated with a given wavelength, amplitude, pulse frequency, pulse time, polarization state or states, angular content, and/or spatial content range.

In some embodiments, the different sub-portions comprise a series of metasurfaces spaced from each other along an optical path. Each metasurface in the series of metasurfaces is configured to reflect a narrower band sub-beam of radiation having the modified wavelength, amplitude, pulse frequency, pulse time, polarization state or states, angular content, and/or spatial content range toward the detector, while collimating and allowing a remaining portion of a diffracted radiation beam to pass through along the optical path.

In some embodiments, the detector comprises multiple separate detectors, or multiple sub-portions of a single detector.

In some embodiments, the different sub-portions are arranged to form a waveguide. The waveguide is configured to receive a diffracted radiation beam, separate the diffracted radiation beam into narrower band sub-beams of radiation having the modified wavelength, amplitude, pulse frequency, pulse time, polarization state or states, angular content, and/or spatial content range; and direct the narrower band sub-beams of radiation through the waveguide toward the detector.

At operation 1406, a detection signal is generated. The detection signal may be generated based on detected narrower band sub-beams of radiation, as described above. The detection signal is generated by a sensor (such as detector 4 in FIG. 3, a camera, and/or other sensors) based on radiation received by the sensor. The detection signal comprises measurement information pertaining to target(s) such as gratings on a semiconductor wafer. For example, the detection signal may be an overlay and/or alignment signal comprising overlay and/or alignment measurement information, and/or other metrology signals. The measurement information (e.g., an overlay value, an alignment value, and/or other information) may be determined using principles of interferometry and/or other principles.

The detection signal comprises an electronic signal that represents and/or otherwise corresponds to radiation reflected from the target(s). Diffracted radiation from a target may comprise + and − order diffracted radiation. The detection signal may indicate a metrology value associated with a diffraction grating target, for example, and/or other information. Generating the detection signal comprises sensing the reflected radiation and converting the sensed reflected radiation into the electronic signal. In some embodiments, generating the detection signal comprises sensing different portions of the reflected radiation from different areas and/or different geometries of the target, and/or multiple targets, and combining the different portions of the reflected radiation to form the detection signal. This sensing and converting may be performed by components similar to and/or the same as detector 4 and/or processors PRO shown in FIG. 3, and/or other components.

In some embodiments, method 1401 comprises detecting reflected radiation from one or more diffraction grating targets. Detecting reflected radiation comprises detecting one or more phase and/or amplitude (intensity) shifts in reflected radiation from one or more geometric features of the target(s). The one or more phase and/or amplitude shifts correspond to one or more dimensions of a target. For example, the phase and/or amplitude of reflected radiation from one side of a target is different relative to the phase and/or amplitude of reflected radiation from another side of the target.

Detecting the one or more phase and/or amplitude (intensity) shifts in the reflected radiation from the target comprises measuring local phase shifts (e.g., local phase deltas) and/or amplitude variations that correspond to different portions of a target. For example, the reflected radiation from a specific area of a target may comprise a sinusoidal waveform having a certain phase and/or amplitude. The reflected radiation from a different area of the target (or a target in a different layer) may also comprise a sinusoidal waveform, but one with a different phase and/or amplitude. Detected reflected radiation also comprises measuring a phase and/or amplitude difference in reflected radiation of different diffraction orders. Detecting the one or more local phase and/or amplitude shifts may be performed using Hilbert transformations, for example, and/or other techniques. Interferometry techniques and/or other operations may be used to measure phase and/or amplitude differences in reflected radiation of different diffraction orders.

In some embodiments, method 1401 comprises determining an adjustment for a semiconductor device manufacturing process. In some embodiments, method 1401 includes determining one or more semiconductor device manufacturing process parameters. The one or more semiconductor device manufacturing process parameters may be determined based on one or more detected phase and/or amplitude variations, an overlay and/or alignment value indicated by the detection signal, and/or other similar systems, and/or other information. The one or more parameters may include a parameter of the radiation (the radiation used for metrology), an overlay value, an alignment value, a metrology inspection location on a layer of a semiconductor device structure, a radiation beam trajectory across a target, and/or other parameters. In some embodiments, process parameters can be interpreted broadly to include a stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

In some embodiments, method 1401 includes determining a process adjustment based on the one or more determined semiconductor device manufacturing process parameters, adjusting a semiconductor device manufacturing apparatus based on the determined adjustment, and/or other operations. For example, if a determined metrology measurement is not within process tolerances, the out of tolerance measurement may be caused by one or more manufacturing processes whose process parameters have drifted and/or otherwise changed so that the process is no longer producing acceptable devices (e.g., measurements may breach a threshold for acceptability). One or more new or adjusted process parameters may be determined based on the measurement determination. The new or adjusted process parameters may be configured to cause a manufacturing process to again produce acceptable devices.

For example, a new or adjusted process parameter may cause a previously unacceptable measurement value to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of method 1401), for example. In some embodiments, method 1401 may include electronically adjusting an apparatus (e.g., based on the determined process parameters). Electronically adjusting an apparatus may include sending an electronic signal, and/or other communications to the apparatus, for example, which causes a change in the apparatus. The electronic adjustment may include changing a setting on the apparatus, for example, and/or other adjustments.

FIG. 15 is a diagram of an example computer system CS that may be used for one or more of the operations described herein. Computer system CS includes a bus BS or other communication mechanism for communicating information, and a processor PRO (or multiple processors similar to and/or the same as processor PRO shown in FIG. 3) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a flat panel or touch panel display or a cathode ray tube (CRT) for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, one or more operations described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Various embodiments of the present systems and methods are disclosed in the subsequent list of numbered clauses. In the following, further features, characteristics, and exemplary technical solutions of the present disclosure will be described in terms of clauses that may be optionally claimed in any combination:
1. A metrology system, comprising: a radiation source configured to form multiple diffracted radiation beams, each of the diffracted radiation beams having an incident wavelength range, amplitude, pulse frequency, pulse time, polarization state or states, angular content, and/or spatial content; a radiation beam demultiplexer, the radiation beam demultiplexer comprising different sub-portions, each of the different sub-portions configured to separate an associated one of the diffracted radiation beams into a narrower band sub-beam of radiation having a modified wavelength range, amplitude, pulse frequency, pulse time, polarization state or states, angular content, and/or spatial content in comparison to the incident wavelength range, amplitude, pulse frequency, pulse time, polarization state or states, angular content, and/or spatial content; and a detector configured to receive narrower band sub-beams of radiation and generate a detection signal.
2. The system of clause 1, wherein the metrology system forms a portion of an alignment sensor, the alignment sensor is configured for a substrate comprising a semiconductor wafer, and the alignment sensor is configured to be used in a semiconductor manufacturing process.
3. The system of any of the previous clauses, wherein the metrology system is configured for measuring alignment of one layer of the wafer relative to another.
4. The system of any of the previous clauses, wherein the different sub-portions comprise one or more metasurfaces, the one or more metasurfaces configured to be usable with one or more lenses, optical fibers, detectors, mirrors, and/or integrated optics.
5. The system of any of the previous clauses, wherein the one or more metasurfaces comprise nano-antennas, meta-atoms, scatterers, and/or nano-particles.
6. The system of any of the previous clauses, wherein the different sub-portions are geometrically configured for different non-overlapping wavelength ranges, amplitudes, pulse frequencies, pulse times, polarization states, angular content, and/or spatial content.
7. The system of any of the previous clauses, wherein each different sub-portion is associated with a different color wavelength range.
8. The system of any of the previous clauses, wherein the different sub-portions comprise adjacent local areas of a single unitary metasurface formed with nano-antennas, meta-atoms, or nano-particles configured for specific non-overlapping radiation wavelength ranges, amplitudes, pulse frequencies, pulse times, polarization states, angular content, and/or spatial content.
9. The system of any of the previous clauses, wherein the different sub-portions comprise separate metasurfaces formed with nano-antennas, meta-atoms, or nano-particles configured for specific non-overlapping radiation wavelength ranges, amplitudes, pulse frequencies, pulse times, polarization states, angular content, and/or spatial content.
10. The system of any of the previous clauses, wherein the nano-antennas, meta-atoms, scatterers, and/or nano-particles comprise blocks of material having heights, widths, lengths, and/or angles of rotation configured for a specific non-overlapping wavelength range, amplitude, pulse frequency, pulse time, polarization state, angular content, and/or spatial content.
11. The system of any of the previous clauses, wherein the nano-antennas, meta-atoms, scatterers, and/or nano-particles comprise free form shapes configured for a specific wavelength range, amplitude, pulse frequency, pulse time, polarization state, angular content, and/or spatial content.
12. The system of any of the previous clauses, wherein the different sub-portions are configured to focus radiation of a specific wavelength range, amplitude, pulse frequency, pulse time, polarization state or states, angular content, and/or spatial content.
13. The system of any of the previous clauses, wherein the different sub-portions are configured to collimate radiation of a specific wavelength range, amplitude, pulse frequency, pulse time, polarization state or states, angular content, and/or spatial content.
14. The system of any of the previous clauses, wherein first sub-portions are configured to disperse narrower band sub-beams of radiation, and second sub-portions are configured to collect and direct the narrower band sub-beams of radiation toward the detector.
15. The system of any of the previous clauses, wherein the first and second sub-portions each comprise a two dimensional (2D) array of adjacent sub-portions.
16. The system of any of the previous clauses, wherein the first and second sub-portions comprise a first metasurface, and a second metasurface spaced from the first metasurface, along an optical path.
17. The system of any of the previous clauses, wherein the first metasurface is configured to receive the diffracted radiation beams from a target on a substrate, and filter the diffracted radiation for a specific wavelength range, amplitude, pulse frequency, pulse time, polarization state or states, angular content, and/or spatial content, and wherein the second metasurface is configured to separate the diffracted radiation beams into the narrower band sub-beams of radiation having the modified wavelength range, amplitude, pulse frequency, pulse time, polarization state or states, angular content, and/or spatial content; and direct the narrower band sub-beams of radiation toward the detector.
18. The system of any of the previous clauses, wherein the different sub-portions are configured to divide and disperse a diffracted radiation beam into a series of non-overlapping wavelength, amplitude, pulse frequency, pulse time, polarization state or states, angular content, and/or spatial content bands, collimate the wavelength, amplitude, pulse frequency, pulse time, polarization state or states, angular content, and/or spatial content bands, and/or focus each of the wavelength, amplitude, pulse frequency, pulse time, polarization state or states, angular content, and/or spatial content bands at a different spot on the detector.
19. The system of any of the previous clauses, further comprising a grating configured to receive a diffracted radiation beam from a target on a substrate, and direct different wavelength, amplitude, pulse frequency, pulse time, polarization state or states, angular content, and/or spatial content ranges of the diffracted radiation beam toward different corresponding sub-portions associated with a given wavelength, amplitude, pulse frequency, pulse time, polarization state or states, angular content, and/or spatial content range.
20. The system of any of the previous clauses, further comprising a liquid crystal polarizing grating and/or a prism configured to receive a diffracted radiation beam from a target on a substrate, and direct different wavelength, amplitude, pulse frequency, pulse time, polarization state or states, angular content, and/or spatial content ranges of the diffracted radiation beam toward different corresponding sub-portions associated with a given wavelength, amplitude, pulse frequency, pulse time, polarization state or states, angular content, and/or spatial content range.
21. The system of any of the previous clauses, wherein the different sub-portions comprise a series of metasurfaces spaced from each other along an optical path, each metasurface in the series of metasurfaces configured to reflect a narrower band sub-beam of radiation having the modified wavelength, amplitude, pulse frequency, pulse time, polarization state or states, angular content, and/or spatial content range toward the detector, while collimating and allowing a remaining portion of a diffracted radiation beam to pass through along the optical path.
22. The system of any of the previous clauses, wherein the detector comprises multiple separate detectors, or multiple sub-portions of a single detector.
23. The system of any of the previous clauses, wherein the different sub-portions are arranged to form a waveguide, the waveguide configured to receive a diffracted radiation beam, separate the diffracted radiation beam into narrower band sub-beams of radiation having the modified wavelength, amplitude, pulse frequency, pulse time, polarization state or states, angular content, and/or spatial content range; and direct the narrower band sub-beams of radiation through the waveguide toward the detector.
24. The system of any of the previous clauses, wherein the radiation source is configured to generate the multiple diffracted radiation beams by directing a first incident radiation beam toward a target on a substrate such that the target diffracts the first incident radiation beam.
25. The system of any of the previous clauses, wherein the metrology system forms a portion of an overlay sensor, the overlay sensor is configured for a substrate comprising a semiconductor wafer, and the overlay sensor is configured to be used in a semiconductor manufacturing process.
26. A metrology method, comprising: forming, with a radiation source, multiple diffracted radiation beams, each of the diffracted radiation beams having an incident wavelength range, amplitude, pulse frequency, pulse time, polarization state or states, angular content, and/or spatial content; separating an associated one of the diffracted radiation beams into a narrower band sub-beam of radiation having a modified wavelength range, amplitude, pulse frequency, pulse time, polarization state or states, angular content, and/or spatial content in comparison to the incident wavelength range, amplitude, pulse frequency, pulse time, polarization state or states, angular content, and/or spatial content, the separating performed with a radiation beam demultiplexer, the radiation beam demultiplexer comprising different sub-portions, each of the different sub-portions configured to perform the separating; and receiving, with a detector, narrower band sub-beams of radiation, and generating a detection signal.
27. The method of clause 26, wherein the metrology method is for an alignment sensor, the alignment sensor is configured for a substrate comprising a semiconductor wafer, and the alignment sensor is configured to be used in a semiconductor manufacturing process.
28. The method of any of the previous clauses, wherein the metrology method is configured for measuring alignment of one layer of the wafer relative to another.
29. The method of any of the previous clauses, wherein the different sub-portions comprise one or more metasurfaces, the one or more metasurfaces configured to be usable with one or more lenses, optical fibers, detectors, mirrors, and/or integrated optics.
30. The method of any of the previous clauses, wherein the one or more metasurfaces comprise nano-antennas, meta-atoms, scatterers, and/or nano-particles.
31. The method of any of the previous clauses, wherein the different sub-portions are geometrically configured for different non-overlapping wavelength ranges, amplitudes, pulse frequencies, pulse times, polarization states, angular content, and/or spatial content.
32. The method of any of the previous clauses, wherein each different sub-portion is associated with a different color wavelength range.
33. The method of any of the previous clauses, wherein the different sub-portions comprise adjacent local areas of a single unitary metasurface formed with nano-antennas, meta-atoms, or nano-particles configured for specific non-overlapping radiation wavelength ranges, amplitudes, pulse frequencies, pulse times, polarization states, angular content, and/or spatial content.
34. The method of any of the previous clauses, wherein the different sub-portions comprise separate metasurfaces formed with nano-antennas, meta-atoms, or nano-particles configured for specific non-overlapping radiation wavelength ranges, amplitudes, pulse frequencies, pulse times, polarization states, angular content, and/or spatial content.
35. The method of any of the previous clauses, wherein the nano-antennas, meta-atoms, scatterers, and/or nano-particles comprise blocks of material having heights, widths, lengths, and/or angles of rotation configured for a specific non-overlapping wavelength range, amplitude, pulse frequency, pulse time, polarization state, angular content, and/or spatial content.
36. The method of any of the previous clauses, wherein the nano-antennas, meta-atoms, scatterers, and/or nano-particles comprise free form shapes configured for a specific wavelength range, amplitude, pulse frequency, pulse time, polarization state, angular content, and/or spatial content.
37. The method of any of the previous clauses, wherein the different sub-portions are configured to focus radiation of a specific wavelength range, amplitude, pulse frequency, pulse time, polarization state or states, angular content, and/or spatial content.
38. The method of any of the previous clauses, wherein the different sub-portions are configured to collimate radiation of a specific wavelength range, amplitude, pulse frequency, pulse time, polarization state or states, angular content, and/or spatial content.
39. The method of any of the previous clauses, wherein first sub-portions are configured to disperse narrower band sub-beams of radiation, and second sub-portions are configured to collect and direct the narrower band sub-beams of radiation toward the detector.
40. The method of any of the previous clauses, wherein the first and second sub-portions each comprise a two dimensional (2D) array of adjacent sub-portions.
41. The method of any of the previous clauses, wherein the first and second sub-portions comprise a first metasurface, and a second metasurface spaced from the first metasurface, along an optical path.
42. The method of any of the previous clauses, wherein the first metasurface is configured to receive the diffracted radiation beams from a target on a substrate, and filter the diffracted radiation for a specific wavelength range, amplitude, pulse frequency, pulse time, polarization state or states, angular content, and/or spatial content, and wherein the second metasurface is configured to separate the diffracted radiation beams into the narrower band sub-beams of radiation having the modified wavelength range, amplitude, pulse frequency, pulse time, polarization state or states, angular content, and/or spatial content; and direct the narrower band sub-beams of radiation toward the detector.
43. The method of any of the previous clauses, wherein the different sub-portions are configured to divide and disperse a diffracted radiation beam into a series of non-overlapping wavelength, amplitude, pulse frequency, pulse time, polarization state or states, angular content, and/or spatial content bands, collimate the wavelength, amplitude, pulse frequency, pulse time, polarization state or states, angular content, and/or spatial content bands, and/or focus each of the wavelength, amplitude, pulse frequency, pulse time, polarization state or states, angular content, and/or spatial content bands at a different spot on the detector.
44. The method of any of the previous clauses, further comprising receiving, with a grating, a diffracted radiation beam from a target on a substrate, and directing different wavelength, amplitude, pulse frequency, pulse time, polarization state or states, angular content, and/or spatial content ranges of the diffracted radiation beam toward different corresponding sub-portions associated with a given wavelength, amplitude, pulse frequency, pulse time, polarization state or states, angular content, and/or spatial content range.
45. The method of any of the previous clauses, further comprising receiving, with a liquid crystal polarizing grating and/or a prism, a diffracted radiation beam from a target on a substrate, and directing different wavelength, amplitude, pulse frequency, pulse time, polarization state or states, angular content, and/or spatial content ranges of the diffracted radiation beam toward different corresponding sub-portions associated with a given wavelength, amplitude, pulse frequency, pulse time, polarization state or states, angular content, and/or spatial content range.
46. The method of any of the previous clauses, wherein the different sub-portions comprise a series of metasurfaces spaced from each other along an optical path, each metasurface in the series of metasurfaces configured to reflect a narrower band sub-beam of radiation having the modified wavelength, amplitude, pulse frequency, pulse time, polarization state or states, angular content, and/or spatial content range toward the detector, while collimating and allowing a remaining portion of a diffracted radiation beam to pass through along the optical path.
47. The method of any of the previous clauses, wherein the detector comprises multiple separate detectors, or multiple sub-portions of a single detector.
48. The method of any of the previous clauses, wherein the different sub-portions are arranged to form a waveguide, the waveguide configured to receive a diffracted radiation beam, separate the diffracted radiation beam into narrower band sub-beams of radiation having the modified wavelength, amplitude, pulse frequency, pulse time, polarization state or states, angular content, and/or spatial content range; and direct the narrower band sub-beams of radiation through the waveguide toward the detector.
49. The method of any of the previous clauses, wherein the radiation source is configured to generate the multiple diffracted radiation beams by directing a first incident radiation beam toward a target on a substrate such that the target diffracts the first incident radiation beam.
50. The method of any of the previous clauses, wherein the metrology method is for an overlay sensor, the overlay sensor is configured for a substrate comprising a semiconductor wafer, and the overlay sensor is configured to be used in a semiconductor manufacturing process.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments.

The descriptions above are intended to be illustrative, not limiting. Thus, it will be apparent to one skilled in the art that modifications may be made as described without departing from the scope of the claims set out below.

1. A metrology system, comprising:
a radiation system configured to form multiple diffracted radiation beams, each of the diffracted radiation beams having an incident wavelength range, amplitude, pulse frequency, pulse time, polarization state or states, angular content, and/or spatial content;
a radiation beam demultiplexer, the radiation beam demultiplexer comprising different sub-portions, each of the different sub-portions configured to separate an associated one of the diffracted radiation beams into a narrower band sub-beam of radiation having a modified wavelength range, amplitude, pulse frequency, pulse time, polarization state or states, angular content, and/or spatial content in comparison to the incident wavelength range, amplitude, pulse frequency, pulse time, polarization state or states, angular content, and/or spatial content; and
a detector configured to receive narrower band sub-beams of radiation and generate a detection signal.

2. The system of claim 1, forming a portion of an alignment sensor, the alignment sensor is configured for a substrate comprising a semiconductor wafer, and the alignment sensor is configured to be used in a semiconductor manufacturing process.

3. The system of claim 2, configured for measuring alignment of one layer of the wafer relative to another.

4. The system of claim 1, wherein the different sub-portions comprise one or more metasurfaces, the one or more metasurfaces configured to be usable with one or more lenses, optical fibers, detectors, mirrors, and/or integrated optics.

5. The system of claim 4, wherein the one or more metasurfaces comprise nano-antennas, metaatoms, scatterers, and/or nano-particles.

6. The system of claim 1, wherein the different sub-portions are geometrically configured for different non-overlapping wavelength ranges, amplitudes, pulse frequencies, pulse times, polarization states, angular content, and/or spatial content.

7. The system of claim 6, wherein each different sub-portion is associated with a different color wavelength range.

8. The system of claim 1, wherein the different sub-portions comprise adjacent local areas of a single unitary metasurface formed with nano-antennas, meta-atoms, scatterers or nano-particles configured for specific non-overlapping radiation wavelength ranges, amplitudes, pulse frequencies, pulse times, polarization states, angular content, and/or spatial content.

9. The system of claim 1, wherein the different sub-portions comprise separate metasurfaces formed with nano-antennas, meta-atoms, scatterers or nano-particles configured for specific nonoverlapping radiation wavelength ranges, amplitudes, pulse frequencies, pulse times, polarization states, angular content, and/or spatial content.

10. The system of claim 8, wherein the nano-antennas, meta-atoms, scatterers, and/or nanoparticles comprise blocks of material having heights, widths, lengths, and/or angles of rotation configured for a specific non-overlapping wavelength range, amplitude, pulse frequency, pulse time, polarization state, angular content, and/or spatial content.

11. The system of claim 8, wherein the nano-antennas, meta-atoms, scatterers, and/or nanoparticles comprise free form shapes configured for a specific wavelength range, amplitude, pulse frequency, pulse time, polarization state, angular content, and/or spatial content.

12. The system of claim 1, wherein the different sub-portions are configured to focus radiation of a specific wavelength range, amplitude, pulse frequency, pulse time, polarization state or states, angular content, and/or spatial content.

13. The system of claim 1, wherein the different sub-portions are configured to collimate radiation of a specific wavelength range, amplitude, pulse frequency, pulse time, polarization state or states, angular content, and/or spatial content.

14. The system of claim 1, wherein first sub-portions are configured to disperse narrower band sub-beams of radiation, and second sub-portions are configured to collect and direct the narrower band sub-beams of radiation toward the detector.

15. The system of claim 14, wherein the first and second sub-portions each comprise a two dimensional (2D) array of adjacent sub-portions.

16. A metrology method, comprising:
forming multiple diffracted radiation beams, each of the diffracted radiation beams having an incident wavelength range, amplitude, pulse frequency, pulse time, polarization state or states, angular content, and/or spatial content;
separating an associated one of the diffracted radiation beams into a narrower band sub-beam of radiation having a modified wavelength range, amplitude, pulse frequency, pulse time, polarization state or states, angular content, and/or spatial content in comparison to the incident wavelength range, amplitude, pulse frequency, pulse time, polarization state or states, angular content, and/or spatial content, the separating performed with a radiation beam demultiplexer, the radiation beam demultiplexer comprising different sub-portions, each of the different sub-portions configured to perform the separating; and
receiving, with a detector, narrower band sub-beams of radiation, and generating a detection signal.

17. The method of claim 16, configured to measure alignment in a semiconductor manufacturing process.

18. The method of claim 16, wherein the different sub-portions comprise one or more metasurfaces, the one or more metasurfaces configured to be usable with one or more lenses, optical fibers, detectors, mirrors, and/or integrated optics.

19. The method of claim 16, wherein the different sub-portions comprise one or more metasurfaces and the one or more metasurfaces comprise nano-antennas, meta-atoms, scatterers, and/or nano-particles.

20. The method of claim 16, wherein the different sub-portions are geometrically configured for different non-overlapping wavelength ranges, amplitudes, pulse frequencies, pulse times, polarization states, angular content, and/or spatial content.
